(19) United States
(12) Patent Application Publication
(10) Pub. No.: US 2010/0219331 A1
(43) Pub. Date: Sep. 2, 2010

(54) Optoelectronic sensor

(75) Inventors: Michael Klein, Waldkirch (DE); Christoph Märkle, Freiburg (DE); Bernhard Schindler, Simonswald (DE)

Correspondence Address: THE NATH LAW GROUP, 112 South West Street, Alexandria, VA, 22314, US

(73) Assignee: Sick AG, Waldkirch (DE)

(21) Appl. No.: 12/656,677

(22) Filed: Feb. 12, 2010

(30) Foreign Application Priority Data
Mar. 2, 2009 (EP) 09100160.2

(51) Int. Cl. H01L 31/09; H01L 31/0232

(52) U.S. Cl. 250/214 R

(57) ABSTRACT

The invention relates to n optoelectronic sensor having a transmitter (12) for the transmission of a transmitted light beam (22) which is extended perpendicular to the detection direction by means of an optical transmission system (24) and a receiver (14) for the reception of received light (28) and for the provision of an electronic received signal, and an evaluation unit (16) for the recording of the received signal and for the outputting of an object detection signal, wherein at least the transmitter (12) and the optical transmission system (24) are arranged in a sensor housing (18) having a front screen (20). To provide an improved sensor which is inexpensive and nevertheless generates a linear transmitted light of high quality, it is proposed that the front screen (20) is overlaid with patterns (40) of light absorbing material for light intensity homogenization in a region (21S) through which the transmitted light (22) passes and/or in a region (21E) through which the received light (28) passes.

The invention relates to an optoelectronic sensor in accordance with the preamble of claim 1.

An optical sensor is known from EP 1 503 226 A2 which is designed as a light probe and has a transmitter for the transmission of transmitted light, a receiver for the reception of transmitted light reflected at an object and an evaluation unit in which the electronic signal of the receiver is evaluated and an object detection signal is output on the detection of reflected transmitted light at an object. In order also to be able to detect structured objects with which only some of the transmitted light beams are reflected back the receiver due to the structures, provision is made in accordance with EP 1 503 226 A2 that the transmitted light beams are expanded by a light scattering film, for example in a linear manner, so that the object to be detected is illuminated over a larger area and a sufficient refection for detection is available if an object is present. If therefore a minimum degree of reflected light is received, the receiver can determine this and an object detection signal is output. The linear expansion of the transmitted light is achieved by means of a film which scatters light, has a large number of microlenses and is arranged between the optical transmission system and a front screen.

An optical sensor is known from DE 10 2007 050 096 A1, wherein a structured front screen is provided for the homogenization of the light beam whose structures are formed from a plurality of optical elements having alternating focal lengths and arranged next to one another. It is disadvantageous that such a front screen can only be manufactured in a very complex and thus expensive manner.

Starting from this prior art, it is the object of the invention to provide an improved optoelectronic sensor which is inexpensive and nevertheless generates a transmitted light of high quality expanded perpendicular to the transmitted beam direction.

This object is satisfied by an optoelectronic senor having the features of claim 1.

Such an optoelectronic sensor has a transmitter for the transmission of a transmitted light beam which is formed perpendicular to the transmission beam direction by means of an optical transmission system in an expanded (approximately linear) shape, a receiver for the reception of received light and for the provision of an electronic received signal, an evaluation unit for the recording of the received signal and for the outputting of an object detection signal wherein at least the transmitter and the optical transmission system are arranged in a sensor housing having a front screen. In accordance with the invention, the front screen is overlaid with patterns of light absorbing material for light intensity homogenization in the region through which the transmitted light passes or in a region through which the received light passes so that the same light intensity is present, where possible, over the whole line transversely to the direction in which the transmitted light is transmitted.

The front screen thus has no changes in its structure and can thus remain inexpensive. The homogenization of the transmitted light beam or received light beam is only achieved by the pattern of light absorbing material in that the light is absorbed more in the regions in which the front screen is overlaid more densely with the light absorbing material than in the regions in which less light absorbing material or no light absorbing material at all is present. Such an overlay of the front screen can be carried out very inexpensively, preferably by printing.

The construction space (spacing between the transmitter or receiver and the associated lens) required due to the optical constraints can be reduced by the use of a Fresnel lens.

if the transmitter, receiver and evaluation unit are arranged together in the sensor housing and if the region of the front screen through which the transmitted light passes is not overlaid by the patterns, the sensor can be formed in a compact manner and the transmitted light can be incident on a possible object in full strength, whereby the transmitted light beam is visible, for example for alignment purposes.

The invention will be explained in detail in the following with reference to an embodiment and to the drawing. There are shown in the drawing:

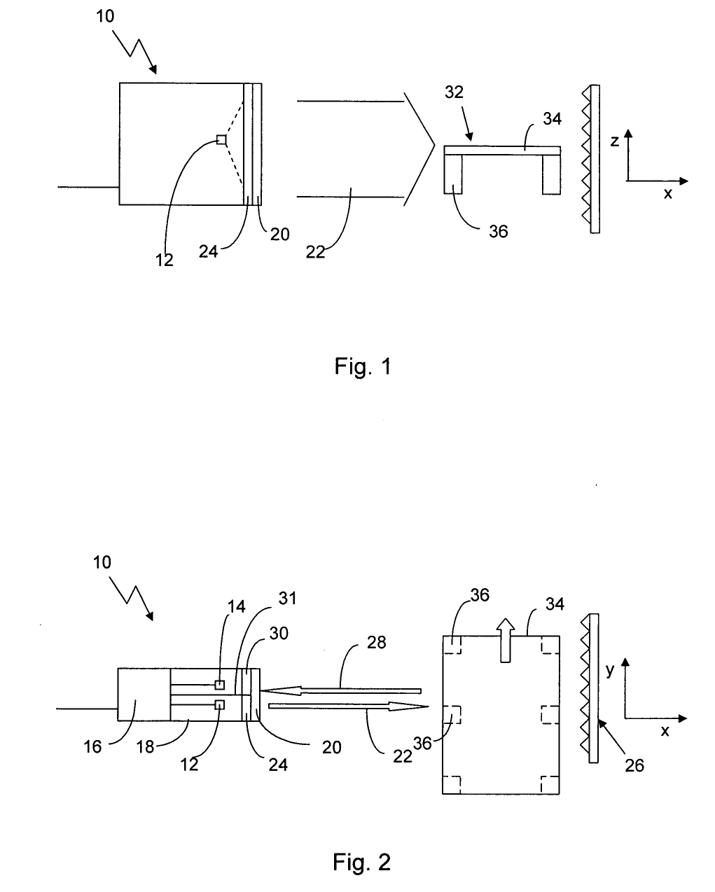

FIGS. 1 and 2 a schematic representation of the sensor in accordance with the invention in an application from two different directions;

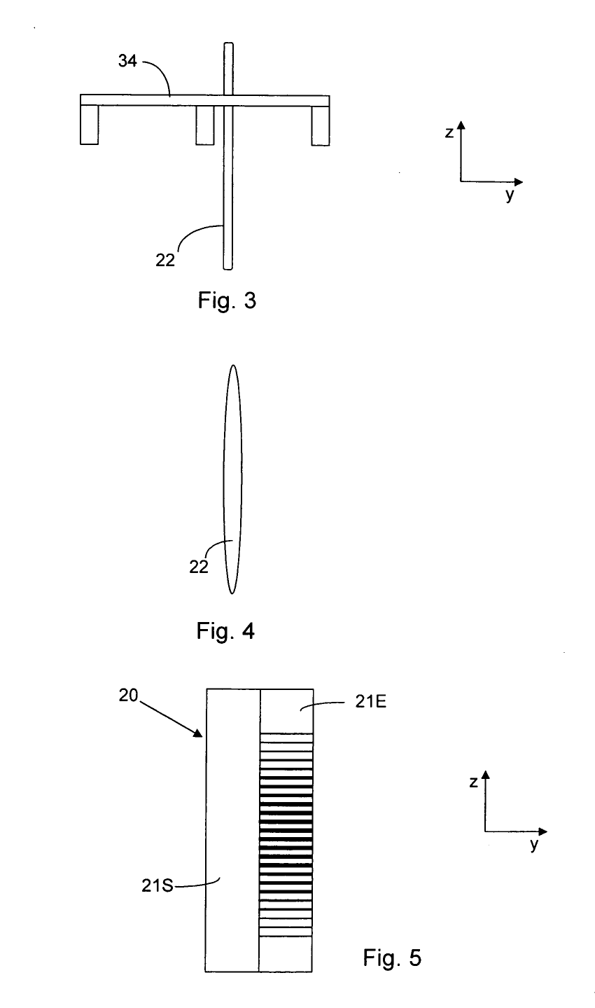

FIGS. 3 and 4 beam profiles of the transmitted light;

FIG. 5 a schematic representation of an embodiment of a front screen;

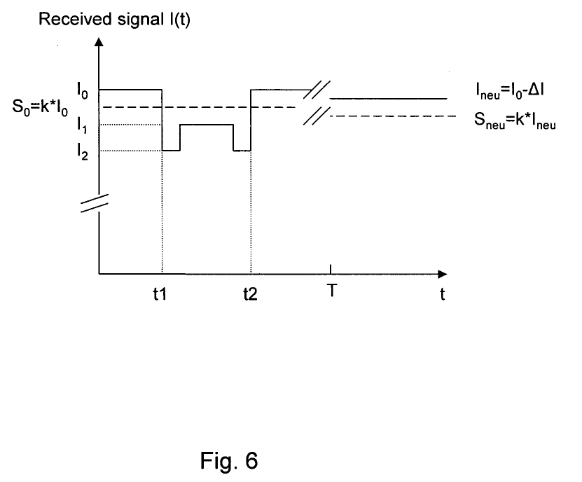

FIG. 6 a schematic diagram of the time extent of the received signal for the illustration of the operation of the sensor in accordance with the invention.

A sensor 10 in accordance with the invention is designed as a light barrier and is shown by way of example as a reflection light barrier in FIGS. 1 and 2. The sensor 10 has a transmitter 12, a receiver 14, designed as a photodiode, for example, and an evaluation unit 16. The transmitter 12, the receiver 14 and the evaluation unit 16 are arranged in a common sensor housing 18 which is covered by a front screen at the front side. The transmitted light 22 transmitted by the sensor 10 is expanded approximately in linear form by an optical transmission system 24 which is associated with the transmitter 12 so that the transmitted light 22 exiting the sensor has an approximately linear transmission profile such as is shown in FIGS. 3 and 4. In accordance with FIG. 3, the transmitted light is almost rectangular in cross-section, with it being a very narrow rectangle to obtain the linear shape. The transmitted light profile in accordance with FIG. 4 is formed in linear fashion by an elongated elliptical shape. The optical transmission system 24 forming the transmitted light profile can be designed as a Fresnel lens, for example, whereby the spacing between the transmitter 12 and the optical transmission system 24 can be kept to a minimum to reduce the construction space.

The linear shape of the transmitted light 22 can likewise be recognized in FIGS. 1 and 2, with the transmitted light being very narrow in the perspective of FIG. 1 and being very wide in the perspective of FIG. 2 so that the transmitted light is therefore formed in linear fashion in the z direction and thus transversely to the direction in which the transmitted light is transmitted.

With a free beam path, the transmitted light 22 is incident on a retroreflector 26 and is reflected back by this in the same direction to the sensor 10 and is received there as received light 28 by the receiver 14 which has an optical reception system 30 arranged in front of it. The optical reception system 30 focuses the likewise linear received light 28 onto the receiver 14 formed as a photodiode.

So that no direct optical crosstalk takes place from the transmitter to the receiver within the housing, an optical dividing wall 31 is preferably provided which separates the transmission channel and the reception channel in the sensor housing 18. The received light is converted in the receiver 14 into an electronic received signal which is recorded by the evaluation unit 16. The received signal is thereupon evaluated in the evaluation unit as to whether an opaque object is present in the transmitted light 22 or not and a detection signal is output as required.

In the embodiment in accordance with FIGS. 1 and 2, the sensor 10 in accordance with the invention serves for the detection of pallets 32. A pallet 32 has a pallet base 34 and pallet feet 36. The optoelectronic sensor 10 is now aligned such that the transmitted light line extends perpendicular to the pallet base 34 so that the pallet base 34 is transported through the transmitted light 22 on the transport of the pallet 32 in the y direction (see also FIG. 3).

Since the pallet base 34 has a relatively small extent in comparison to the extent of the transmitted light 22 in the z direction, it only interrupts the transmitted light section-wise so that a large portion of the transmitted light always reaches the reflector 26 and is reflected back into the receiver 14. It is therefore a particular object of the sensor in accordance with the invention to recognize a relatively small intensity change and to output a detection signal as reliably and as securely as possible when at least a pallet foot 36 of a pallet 32 is located in the beam path. For this purpose, the sensor 10 works as explained in the following with reference to FIG. 6:

At the start, with a free beam path, the received intensity is first determined at the receiver 14 and the corresponding electronic received signal I₀ is stored. Then, a recognition threshold value S₀ is fixed in the evaluation unit 16 which corresponds to a fixed percentage of the received signal with a free beam path.

S₀=k*I₀ 1 where k<1

This recognition threshold value S₀ must, however, be higher than a received signal I₁ which corresponds to the received intensity when at least the pallet base 34 is located in the beam path of the transmitted light 22, for example in the time between t1 and t2. It is then ensured that a pallet is present if the recognition threshold value S₀ is fallen below. This naturally also applies when a pallet foot 36 should also enter into the beam path since the signal I₂ then received is even smaller than the received signal I₁ when only the pallet base 34 is in the transmitted light 22.

After the end of a specific time T, this may be a plurality of seconds, for example, or even minutes or hours, the received signal I_{new} is automatically determined again with a free beam path, that is without pallets, and the previous value for I₀ stored in the evaluation unit 16 is overwritten. Starting from this new received signal I_{new} with a free beam path, a new recognition threshold value S_{new} is calculated with the same percentage and is stored as a new recognition threshold value S_{new}.

S_{new}=k*I_{new}

Work is continued with this new recognition threshold value S_{new} until, after a renewed time lapse, a new recognition threshold value is again determined in the same manner. The recognition threshold value is tracked over and over again in this manner. If the time interval T is very short, for example seconds, the tracking is even quasi-continuous.

As already explained above, a respective transmitted light profile is shown schematically in cross-section in FIGS. 3 and 4. So that the recognition of a pallet base 34 located in the beam path 22 is independent of the location of the occurrence of the pallet base 34, the received signal I₁ should be independent of the x and z positions.

To ensure the independence in the z direction, that is along the transmitted light line, the transmitted light should be homogeneous, which makes high demands on the optical transmission system. They can, however, be reduced if the homogenization can be effected in a different manner. Provision is made for this purpose in accordance with the invention that the front screen 20 is overlaid with patterns 40 of light absorbing material in the region 21S through which the transmitted light 22 passes through the front screen 20 or in the region 21E through which the received light 28 passes through the front screen 20. The material is preferably applied to the front screen 20 by printing. The transmitted light 22 or received light 28 is thus ultimately attenuated to different degrees in different regions of the front screen by absorption at the material so that ultimately a homogenization of the light intensity in the z direction is achieved. A printing of only the receiver-side region 21E is advantageous since then the transmitted light emerges at full luminous intensity and reflections of the transmitted light at an object, e.g. the pallet base 34, can be more easily recognized with the naked eye for adjustment purposes. The patterns 40 for the printing of the front screen can be formed in different manners. A stripe pattern 40 is shown by way of example in FIG. 5 which attenuates the transmitted light more centrally in the z direction than upwardly or downwardly toward the margins.

The independence in the x direction is ensured in that the transmitted light 22 transmitted by the sensor 10 is aligned parallel through the optical transmission system 24.

An optoelectronic sensor is thus provided overall with which an object can be detected when it is located in the detection zone specified by the transmitted light beam path 22 and extended in the z direction, with the opaque object having to cause a certain minimum coverage of the transmitted light so that the received signal for the detection falls below a preset threshold.

1. An optoelectronic sensor having a transmitter (12) for the transmission of a transmitted light beam (22) which is extended perpendicular to a transmitted beam direction by means of an optical transmission system (24), a receiver (14) for the reception of received light (28) and for the provision of an electronic received signal and an evaluation unit (16) for the recording of the received signal and for the outputting of an object detection signal, wherein at least the transmitter (12) and the optical transmission system (24) are arranged in a sensor housing (18) having a front screen (20), characterized in that the front screen (20) is overlaid with patterns (40) of light absorbing material for light intensity homogenization in a region (21S) through which the transmitted light (22) passes and/or in a region (21E) through which the received light (28) passes.

2. A sensor in accordance with claim 1, characterized in that the front screen (20) is printed.

3. A sensor in accordance with claim 1, characterized in that the optical transmission system (24) has a Fresnel lens.

4. A sensor in accordance with claim 1, characterized in that the transmitter (12), the receiver (14) and the evaluation unit (16) are arranged together in the sensor housing (18) and the region (21S) of the front screen (20) through which the transmitted light (28) passes is not overlaid with the patterns.
